(19) United States
(12) Patent Application Publication
(10) Pub. No.: US 2013/0344274 A1
(43) Pub. Date: Dec. 26, 2013

(54) PRESSURE-SENSITIVE ADHESIVE TAPE FOR PROTECTING SURFACE OF SEMICONDUCTOR PARTS

(71) Applicants: Junji Fukuhara, Osaka (JP); Yukio Arimitsu, Osaka (JP)

(72) Inventors: Junji Fukuhara, Osaka (JP); Yukio Arimitsu, Osaka (JP)

(73) Assignee: NITTO DENKO CORPORATION, Ibaraki-shi, Osaka (JP)

(21) Appl. No.: 13/991,998

(22) PCT Filed: Jan. 18, 2012
(86) PCT No.: PCT/JP2012/050949

§ 371 Date: Sep. 16, 2013

(30) Foreign Application Priority Data
Jan. 20, 2011 (JP) 2011-010066

(51) Int. Cl. H01L 23/29

(52) U.S. Cl. CPC H01L 23/296
USPC 428/41.4

(57) ABSTRACT

The present invention is for providing a pressure-sensitive adhesive tape for protecting the surface of semiconductor parts which transfers little foreign matter to an object (part) to be adhered in a manufacturing process, the pressure-sensitive adhesive tape comprising at least a base material film, a pressure-sensitive adhesive layer, and a peeling liner, the base material film having the pressure-sensitive adhesive layer on one surface thereof, and the peeling liner using an unprocessed plastic film which does not contain a releasing layer being formed on the pressure-sensitive adhesive layer.

### TECHNICAL FIELD

The present invention relates to a pressure-sensitive adhesive tape for protecting the surface of semiconductor parts and, more particularly, to a pressure-sensitive adhesive tape for protecting surface which is used for the purpose of protecting the light-receiving section side of an image sensor when the image sensor using a solid-state imaging device is produced, and which allows a reduction in the number of transfer foreign matter to an object (the light-receiving section side of the image sensor) to be adhered.

### BACKGROUND ART

As shown in Patent Literatures 1 to 3, there is known a pressure-sensitive adhesive tape aimed at fixing and protection of parts in a manufacturing process when electricity, electronic parts and semiconductor parts are produced. Examples of such a pressure-sensitive adhesive tape include a tape in which a removable acrylic pressure-sensitive adhesive layer is provided to a base material film, and a tape in which a silicone-based pressure-sensitive adhesive layer having high heat resistance in a heating process is provided. The pressure-sensitive adhesive tape is peeled when a predetermined treatment process is completed. In this case, transfer foreign matter from the pressure-sensitive adhesive layer to the parts occurs.

Further, in a small camera mounted on a portable telephone, or the like, CCD-type and CMOS-type image sensors (solid-state imaging device) are being widely used. This small camera is generally constructed from components such as an imaging element, an infrared cut filter, an optical lens, and a lens holder. In such a camera, one of the requirements associated with increased high resolution thereof includes a reduction in noise due to attachment of dust or the like attached to an imaging element.

Thus, as with the above electricity, electronic parts and semiconductor parts, the pressure-sensitive adhesive tape is bonded to the light-receiving section side of the image sensor for the purpose of preventing flaws on the image sensor surface and the adhesion of dirt, whereby an approach to avoid flaws and the adhesion of transfer foreign matter as dirt in mounting and manufacturing processes is taken. The presence of the transfer foreign matter is likely to directly exert an influence on imaging in the image sensor.

Since the cause of the occurrence of the transfer foreign matter is believed to be mainly pressure-sensitive adhesive origin, a reduction in the number of the pressure-sensitive adhesive layer-derived transfer foreign matter is being promoted using a surface protection pressure-sensitive adhesive tape using a polymer from which a low molecular weight component is eliminated for a pressure-sensitive adhesive layer, and a surface protection pressure-sensitive adhesive tape in which various types of additives are blended into the pressure-sensitive adhesive layer in order to improve heat resistance in a heating process for soldering or the like.

However, in the case of a pressure-sensitive adhesive tape with a peeling liner, a releasing agent for the releasing layer (for example, silicone-based releasing layer, fluorosilicone-based releasing layer, or the like) used as the releasing layer in a conventional peeling liner is transferred to a pressure-sensitive adhesive layer, a transferred releasing agent thereof is retransferred to an object to be adhered, and therefore can be detected as foreign matter of the surface of the object to be adhered. Thus, while a releasing agent for preventing transfer to a pressure-sensitive adhesive layer has been studied more than before, the anxiety of the transfer of the releasing agent has not been still erased.

### CITATION LIST

### Patent Literature

[Patent Literature 1]

Japanese Patent Laid-Open No. 2008-201899

[Patent Literature 2]

Japanese Patent Laid-Open No. 2006-332419

[Patent Literature 3]

Japanese Patent Laid-Open No. 2006-077072

### SUMMARY OF INVENTION

### Technical Problem

The present invention is an object to provide a pressure-sensitive adhesive tape for protecting the surface of semiconductor parts which transfers little foreign material to an object (part) to be adhered in a manufacturing process.

### Solution to Problem

The present inventors have achieved the above object as a result of the keen study:

1. A pressure-sensitive adhesive tape for protecting surface comprising at least a base material film, a pressure-sensitive adhesive layer, and a peeling liner, the base material film having the pressure-sensitive adhesive layer on one surface thereof, and the peeling liner using an unprocessed plastic film which does not comprises a releasing layer being laminated on the pressure-sensitive adhesive layer.
2. The pressure-sensitive adhesive tape for protecting surface according to 1, wherein the peeling liner comprises polyethylene terephthalate or polyethylene naphthalate.
3. The pressure-sensitive adhesive tape for protecting surface according to 1 or 2, wherein the pressure-sensitive adhesive layer is an addition reaction-type silicone-based pressure-sensitive adhesive layer.
4. The pressure-sensitive adhesive tape for protecting surface according to any one of 1 to 3, wherein a peeling force of the peeling liner from the pressure-sensitive adhesive layer surface is 1 N/50 mm or less, preferably 0.5 N/50 mm or less.
5. The pressure-sensitive adhesive tape for protecting surface according to any one of 1 to 4, wherein an initial pressure-sensitive adhesive force at normal temperature is 0.05 N/20 mm or less, and an initial adhesive force after 260° C. reflow is 0.50 N/20 mm or less.

### Advantageous Effect of Invention

In a pressure-sensitive adhesive tape for protecting the surface of a semiconductor of the present invention comprising at least a base material film, a pressure-sensitive adhesive layer and a peeling liner, the base material film has the pressure-sensitive adhesive layer on one surface thereof, and the peeling liner using an unprocessed plastic film which does not contain a releasing layer is formed on the pressure-sensitive adhesive layer. The fact that the releasing layer is not contained in the peeling liner prevents the occurrence of the transfer of the releasing agent to the pressure-sensitive adhesive layer surface, and more specifically makes it possible to prevent retransfer to an object to be adhered, resulting in a reduction in the number of transfer foreign matter to the object to be adhered.

Particularly, if the pressure-sensitive adhesive layer is an addition reaction-type silicone-based pressure-sensitive adhesive layer, the blending ratio of a silicone rubber component to a silicone resin component can be adjusted to control the adhesive force. Further, if an adhesive force is lower than that of a pressure-sensitive adhesive comprising other resins, the adhesive force is reduced particularly with respect to the peeling liner, thus eliminating the necessity to provide a peeling agent layer to the peeling liner itself and eventually preventing the occurrence of the transfer of the releasing agent to the pressure-sensitive adhesive layer surface.

Furthermore, the peeling force of the peeling liner from the pressure-sensitive adhesive layer surface should be 1 N/50 mm or less, preferably 0.50 N/50 mm or less, or an initial adhesive force at normal temperature should be 0.05 N/20 mm or less. More specifically, reducing the adhesive force of the pressure-sensitive adhesive layer eliminates the necessity to provide the peeling agent layer to the peeling liner.

### DESCRIPTION OF EMBODIMENTS

A peeling liner in a pressure-sensitive adhesive tape for protecting surface of the present invention is not subjected to a processing with a releasing agent (for example, a silicone-based releasing agent and a fluorosilicone-based releasing agent) which is publicly known as a releasing layer in the peeling liner, and to any processing for imparting removability, and comprises a plastic film, the surface of which is not processed.

As the peeling liner, for example, a polyolefin-based resin such as polyethylene and polypropylene, and a film comprising a polyester-based resin or the like such as polyethylene terephthalate and polyethylene naphthalate can be used. Further, among these films, polyethylene terephthalate and polyethylene naphthalate are particularly preferable.

The thickness of the peeling liner can be appropriately selected within the extent not to impair handleability or the like, but is commonly about 10 to 200 μm, preferably about 20 to 100 μm.

A base material film in the pressure-sensitive adhesive tape for protecting surface of the present invention may be a base material which is generally used in a pressure-sensitive adhesive tape, and includes, for example, a plastic film comprising a plastic such as a polyolefin-based resin such as polyethylene, a polyester-based resin such as polyethylene terephthalate and polyethylene naphthalate, or a vinyl chloride-based resin, a vinyl acetate-based resin, a polyimide-based resin, a fluoro-based resin, and cellophane; paper such as craft paper and Japanese paper; cloth of woven fabrics or non-woven fabrics such as single or blended fabrics comprising a fibrous substance or the like of natural fibers, semisynthetic fibers or synthetic fibers such as Manila hemp, pulp, rayon, acetate fibers, polyester fibers, polyvinyl alcohol fibers, polyamide fibers, and polyolefin fibers; a rubber sheet comprising natural rubber, butyl rubber, or the like; a foam sheet with a foam comprising polyurethane, polychloroprene rubber, or the like; a metal foil such as an aluminum foil and a copper foil; and a composite thereof.

Among these base material films, there are preferably used a plastic film such as a polyethylene film and a polyester film (a polyethylene terephthalate film or the like) when used without a heating process or in a heating process at a comparatively low temperature (160° C. or lower), a polyester film (a polyethylene naphthalate film, or the like) when used in a heating process at 200° C. or lower, and a polyimide-based resin when used in a heating process at 200° C. or higher. Thus, the base materials can be used differently according to a process to be used. Note that the base materials may be any of a transparent one, a semitransparent one, or an opaque one.

A surface processing may be applied to the base materials in order to enhance the anchor force of the pressure-sensitive adhesive. Examples of the surface processing include a corona discharge processing, a sputter processing, a low-pressure UV processing, a plasma processing, and an alkali metal etching processing. Among these surface processing methods, the sputter processing which is capable of increasing surface area which has excellent heat resistance and in which an adhesion layer is formed by physically devastating the surface is excellent. The thickness of the base materials can be appropriately selected within the extent not to impair handleability thereof, but is generally about 10 to 500 μm, preferably about 20 to 100 μm.

A pressure-sensitive adhesive layer of the pressure-sensitive adhesive tape for protecting surface of the present invention can be obtained by being applied to one surface of the base material film, then dried, cross-linked, and cured. It is desirable that the thickness of the pressure-sensitive adhesive layer is preferably 1 to 30 μm, more preferably 3 to 30 μm, even more preferably 5 to 20 μm. In the case of less than 1 μm, the pressure-sensitive adhesive layer is peeled from a sensor in a high temperature atmosphere. Further, in the case of exceeding 30 μm, the pressure-sensitive adhesive layer cannot be peeled when peeled.

A pressure-sensitive adhesive base polymer used in the above pressure-sensitive adhesive layer may be a pressure-sensitive adhesive which is commonly used in a pressure-sensitive adhesive tape and includes, for example, a rubber-based pressure-sensitive adhesive, an acrylic pressure-sensitive adhesive, and a silicone-based pressure-sensitive adhesive. Particularly, the acrylic pressure-sensitive adhesive and silicone-based pressure-sensitive adhesive which have excellent removability are preferred. For example, the silicone-based pressure-sensitive adhesive may be any silicone-based pressure-sensitive adhesive as long as it has heat resistance against the heating process, and for example, silicone-based pressure-sensitive adhesive or the like having 35% or more of toluene insoluble described in Japanese Patent Laid-Open No. 2003-193226 can be used. Further, the acrylic pressure-sensitive adhesive having excellent heat resistance may be acceptable.

The pressure-sensitive adhesive layer of the present invention is not particularly limited so long as it has adhesiveness and heat resistance, and includes, for example, an addition reaction-type silicone-based pressure-sensitive adhesive and an acrylic pressure-sensitive adhesive layer. The addition reaction-type silicone pressure-sensitive adhesive layer can be formed by containing silicone rubber or a silicone resin comprising, for example, organopolysiloxane as a main component, and adding a cross-linking agent thereto followed by curing to form a pressure-sensitive adhesive layer. In this way, the pressure-sensitive adhesive increases cohesion force by generally adding the cross-linking agent so as to achieve three-dimensional structuring. Besides, a tackifier, an antioxidant, other additives, or the like can be blended into the pressure-sensitive adhesive as necessary.

As the silicone rubber, various types thereof used in a silicone-based pressure sensitive adhesive can be used particularly with no limit. For example, organopolysiloxane comprising dimethylsiloxane as a main constitutional unit can be preferably used. A vinyl group, and other functional groups may be introduced into organopolysiloxane as necessary. The weight-average molecular weight of organopolysiloxane is generally 100,000 or more, desirably 100,000 to 1,000,000, particularly preferably 150,000 to 500,000.

As a silicone resin, various types thereof which are used in the silicone-based pressure sensitive adhesive can be used particularly with no limit. For example, organopolysiloxane comprising a copolymer having at least any one unit selected from an M unit (R₃SiO_{1/2}), a Q unit (SiO₂), a T unit (RSiO_{3/2}) and a D unit (R₂SiO) (in the units, R represents a monovalent hydrocarbon radical or a hydroxyl group) can be preferably used. Organopolysiloxane comprising the copolymer has an OH group, and besides various functional groups such as a vinyl group may be introduced thereinto as necessary. A functional group to be introduced may be one that causes a cross-linking reaction. As the copolymer, an MQ resin comprising an M unit and a Q unit is preferable. While the ratio (molar ratio) of the M unit to the Q unit, the T unit or the D unit is not particularly limited, it is preferred to use the former:the latter=about 0.3:1 to 1.5:1, preferably about 0.5:1 to 1.3:1.

The blending ratio (weight ratio) of the silicone rubber to the silicone resin is preferably the former:the latter=about 100:0 to 100:220, more preferably the use of about 100:0 to 100:180, further even more preferably the use of 100:0 to 100:100. The silicone rubber and the silicone resin may be used simply by blending them, or may be a partial condensate thereof.

The blend generally contains a cross-linking agent in order to make the blend a cross-linked structure. Examples of the cross-linking agent include a siloxane-based cross-linking agent having a SiH group and a peroxide-based cross-linking agent. As the peroxide-based cross-linking agent, various types thereof which are conventionally used in the silicone-based pressure sensitive adhesive can be used particularly with no limit. Examples thereof include benzoyl peroxide, t-butyl peroxybenzoate, dicumyl peroxide, t-butyl cumyl peroxide, t-butyl oxide, 2,5-dimethyl-2,5-di-t-butylperoxy hexane, 2,4-dichloro-benzoyl peroxide, di-t-butylperoxy-di-isopropylbenzene, 1,1-bis(t- butylperoxy)-3,3,5-trimethyl-cyclohexane, and 2,5-dimethyl-2,5-di-t-butylperoxyhexine-3.

Further, as the siloxane-based cross-linking agent, for example, polyorganohydrogensiloxane having at least an average of two silicon atom-bound hydrogen atoms in the molecule is used. While examples of a silicon atom-bound organic group include an alkyl group, a phenyl group, and an alkyl halide group, a methyl group is preferable because of ease of its synthesis and handling. While the skeleton structure of siloxane may be any of a straight-chain form, a branched-chain form, and a ring-chain form, the straight-chain form is frequently used.

The acrylic pressure-sensitive adhesive is specifically a pressure-sensitive adhesive comprising an acrylic polymer obtained from the copolymerization of monomers containing at least alkyl (meth)acrylate. Examples of alkyl (meth)acrylate referred herein include methyl (meth)acrylate, ethyl (meth)acrylate, butyl (meth)acrylate, isoamyl (meth)acrylate, n-hexyl (meth) acrylate, 2-ethylhexyl (meth) acrylate, isooctyl (meth)acrylate, isononyl (meth)acrylate, decicyl (meth)acrylate, and dodecyl (meth)acrylate. The acrylic pressure-sensitive adhesive has comparatively high heat resistance and is the most preferable pressure-sensitive adhesive in the present invention.

The acrylic polymer may contain the unit corresponding to other monomer components which can be copolymerized with the (meth)acrylate alkyl ester as necessary for the purpose of modification of a cohesion force, heat resistance, or the like. Examples of such monomer components include a carboxyl group-containing monomer such as acrylic acid, methacrylic acid, carboxyethyl (meth)acrylate, carboxypentyl (meth)acrylate, itaconic acid, maleic acid, fumaric acid, and crotonic acid; an acid anhydride monomer such as maleic anhydride and itaconic anhydride; a hydroxyl group-containing monomer such as 2-hydroxyethyl (meth)acrylate, 2-hydroxypropyl (meth) acrylate, 4-hydroxybutyl (meth)acrylate, 6-hydroxyhexyl (meth)acrylate, 8-hydroxyoctyl (meth) acrylate, 10-hydroxydecyl (meth)acrylate, 12-hydroxylauryl (meth)acrylate, and (4-hydroxymethylcyclohexyl)methyl (meth) acrylate; a sulfonic acid group-containing monomer such as styrenesulfonic acid, allylsulfonic acid, 2-(meth)acrylamide-2-methylpropanesulfonic acid, (meth) acrylamidepropanesulfonic acid, sulfopropyl (meth) acrylate, and (meth) acryloyloxynaphthalenesulfonic acid; a phosphate group-containing monomer such as 2-hydroxyethylacryloyl phosphate; glycidyl ester (meth)acrylate, (meth)acrylamide, N-hydroxymethylamide (meth)acrylate, alkylamino alkylester (meth)acrylate (for example, dimethylaminoethyl methacrylate, and t-butylaminoethyl methacrylate), N-vinylpyrrolidone, acryloylmorpholine, vinyl acetate, vinyl propionate, styrene, acrylonitrile; and cycloalkyl ester (meth)acrylate (for example, cyclopentyl ester, and cyclohexyl ester). One or more kinds of these copolymerizable monomer components can be used. The amount of the copolymerizable monomers used is preferably 70% by weight or less of the total monomer component, more preferably 40% by weight or less.

Furthermore, the acrylic polymer is capable of containing a multifunctional monomer or the like as a monomer component for copolymerization in order to form a cross linking as necessary. Examples of such a multifunctional monomer include hexanediol di(meth)acrylate, (poly)ethyleneglycol di(meth)acrylate, (poly) propyleneglycol di(meth)acrylate, neopentylglycol di(meth)acrylate, pentaerythritol di(meth)acrylate, trimethylolpropanetri (meth) acrylate, pentaerythritol tri(meth)acrylate, dipentaerythritolhexa (meth) acrylate, epoxy (meth)acrylate, polyester (meth)acrylate, and urethane (meth)acrylate. One or more kinds of these multifunctional monomers can be also used. The amount of the multifunctional monomers used is preferably 70% by weight or less of the total monomer component, more preferably 30% by weight or less thereof in terms of pressure-sensitive adhesive properties or the like.

Further, these acrylic pressure-sensitive adhesives may be capable of containing appropriate cross-linking agents. As one example, there is an isocyanate cross-linking agent, an epoxy cross-linking agent, an aziridine-based compound, and a chelate-based cross-linking agent.

While the amount of the cross-linking agent used is not particularly limited, for example, with respect to 100 parts by weight of the acrylic polymer, 0.1 to 15 parts by weight is preferable, and 1 to 10 parts by weight is more preferable.

The pressure-sensitive adhesive layer may contain various types of additives or the like such as tackifier, an antioxidant, a filler, a pigment, a dye, and a silane coupling agent as necessary.

In the present invention, if the peeling force of the peeling liner from the pressure-sensitive adhesive layer surface is 1 N/50 mm or less, the pressure-sensitive adhesive tape for protecting surface can be easily peeled from the peeling liner, thus improving workability. In addition, if an initial adhesive force at normal temperature to glass is 0.05 N/20 mm or less, and an initial adhesive force after 260° C. reflow is 0.50 N/20 mm or less, the pressure-sensitive adhesive tape is easily peeled from the surface to be protected during rework of the pressure-sensitive adhesive tape for protecting surface or during the peeling and removal after reflow, and a deposit of the pressure-sensitive adhesive is not formed on the surface to be protected.

These properties are realized by the silicone-based pressure-sensitive adhesive layer with weak adhesive force and an alkyl-based pressure-sensitive adhesive layer with high cross-linking density. On top of that, the pressure-sensitive adhesives having such an adhesive force have enabled the use of an unprocessed plastic film having no releasing layer as a peeling liner.

### EXAMPLES

Hereinafter, while the present invention will be described in more details on the basis of Examples, performance test examples will be illustrated together with Comparative Examples, and excellent advantageous effects of the present invention will be demonstrated, the present invention is not limited thereto.

### Example 1

Eighteen percent by weight of a toluene solution obtained by adding 0.5 parts of a platinum-based catalyst to 100 parts of an addition reaction-type silicone-based pressure-sensitive adhesive (silicone rubber:silicone resin=95:5) were applied onto one surface of a polyimide film (Kapton 200H, manufactured by Du Pont-Toray Co., Ltd.: 50 μm-thickness), and heated at 150° C. for three minutes to form a silicone-based pressure-sensitive adhesive layer having a thickness of 6 μm. A polyethylene terephthalate film (trade name “Lumirror S-10”, manufactured by Toray Industries, Inc.; thickness: 50 μm) which was not release-processed as a peeling liner was bonded onto the silicone-based pressure-sensitive adhesive layer to obtain a pressure-sensitive adhesive tape for protecting surface.

### Comparative Example 1

A pressure-sensitive adhesive tape for protecting surface was obtained in the same way as in Example 1 except that a polyester film (trade name “MRS-50”, manufactured by Mitsubishi Chemical Corporation; thickness: 50 μm) having a fluorosilicone-based releasing layer as the peeling liner was used in the above Example 1.

### Comparative Example 2

A pressure-sensitive adhesive tape for protecting surface was obtained in the same way as in Example 1 except that a polyester film (trade name “Cerapeel MD(A)(R)”, manufactured by Toyo Metallizing Co., Ltd.; thickness: 38 μm) having a silicone-based releasing layer as the peeling liner was used in the above Example 1.

### Comparative Example 3

A pressure-sensitive adhesive tape for protecting surface was obtained in the same way as in Example 1 except that the peeling liner was not bonded in the above Example 1.

### Example 2

Twenty percent by weight of a toluene solution obtained by adding 0.5 parts of a platinum-based catalyst to 100 parts of an addition reaction-type silicone-based pressure-sensitive adhesive (silicone rubber: silicone resin=80:20) were applied onto one surface of a polyimide film (Kapton 200H, manufactured by Du Pont-Toray Co., Ltd.: 50 μm-thickness), and heated at 150° C. for three minutes to form a silicone-based pressure-sensitive adhesive layer having a thickness of 10 μm. A polyethylene terephthalate film (trade name “Lumirror S-10”, manufactured by Toray Industries, Inc.; thickness: 50 μm) which was not release- processed as a peeling liner was bonded onto the silicone-based pressure-sensitive adhesive layer to obtain a pressure-sensitive adhesive tape for protecting surface.

### Comparative Example 4

A pressure-sensitive adhesive tape for protecting surface was obtained in the same way as in Example 1 except that the polyester film (trade name “MRS-50”, manufactured by Mitsubishi Chemical Corporation; thickness: 50 μm) having a fluorosilicone-based releasing layer was used as the peeling liner in the above Example 2.

[Performance test of Pressure-Sensitive Adhesive Tape for Protecting Surface]

Surface contamination properties (particles) and an initial adhesive force on each of the pressure-sensitive adhesive tapes obtained from the above Example 1 and Comparative Examples 1, 2 and 3 were evaluated by means of each of the tests listed below to obtain the results of Table 1.

### (1) Surface Contamination Properties (Particles)

A pressure-sensitive adhesive tape was bonded to a semiconductor wafer, top 260° C. reflow heated using a heater (Model No. CLF-104C), manufactured by Noritake Co., Limited, and then the pressure-sensitive adhesive tape was peeled. The number of particles of 1.6 μm or more on the wafer after the peeling of the pressure-sensitive adhesive tape was measured using a surface foreign matter inspection apparatus (trade name “Surfscan 6200”, manufactured by KLA-Tencor Corporation).

### (2) Adhesive Force

Each of the adhesive forces at normal temperature and after the 260° C. reflow performed using the heater (Model No. CLF-104C), manufactured by Noritake Co., Limited, was measured with a tension test apparatus. An object to be adhered for the test was a glass surface and the test was performed at a 180° peeling and at a peeling speed of 300 mm/minute.

### (3) Peeling Force of Peeling Liner

The back surface side of a base material film was temporarily pressure-bonded to a stainless steel, and the peeling liner peeling force (180° peeling, and a peeling speed of 300 mm/minute) of the above sample was measured with a tension test apparatus.

TABLE 1

| | | | Comparative | Comparative | Comparative | | Comparative |
|---|---|---|---|---|---|---|---|
| Item | | Example 1 | Example 1 | Example 2 | Example 3 | Example 2 | Example 4 |
| Adhesive | Normal | 0.006 | 0.007 | 0.006 | 0.006 | 0.034 | 0.035 |
| force to | temperature | | | | | | |
| glass | After 260° C. | 0.046 | 0.046 | 0.045 | 0.045 | 0.440 | 0.430 |
| (N/20 mm) | reflow | | | | | | |

| | | | | | | |
|---|---|---|---|---|---|---|
| Peeling liner peeling | 0.028 | 0.094 | 0.025 | — | 0.066 | 0.049 |
| force | | | | | | |
| Number of particles | 11 | 39 | 260 | 10 | 16 | 180 |
| (particles/5 cm²) | | | | | | |

As is clear from Table 1, when looking at resistance to glass adhesive forces at normal temperature and after the 260° C. reflow in Example 1 and Comparative Examples 1 to 3, it is found that all Examples provide comparable results, and that whether or not there is a peeling liner, or whether or not there is a releasing agent layer exerts no influence on the resistance to glass adhesive force.

However, it is found that the pressure-sensitive adhesive tapes of Comparative Examples 1 and 2 using the peeling liner in which the release processing of the silicone-based releasing layer and the fluorosilicone-based releasing layer has been made have much transfer foreign matter in comparison with the pressure-sensitive adhesive tape of Comparative Example 3 to which the peeling liner is not bonded, and that according to the results, a releasing agent is retransferred from the releasing agent layer formed on the peeling surface of the peeling liner described in Comparative Examples 1 and 2.

In contrast to this, as is clear from the results of Example 1, it is found that the pressure-sensitive adhesive tape for protecting surface of the present invention using a polyethylene terephthalate film which is not release-processed as the peeling liner shows the number of particles comparable to that of Comparative Example 3 which uses no peeling liner, thus making it possible to reduce the number of transfer foreign matter with no retransfer of the releasing agent according to Example 1.

When looking at the resistance to glass adhesive force at normal temperature and after the 260° C. reflow in Example 2 and Comparative Example 4, it is found that all Examples provide comparable results, and that whether or not there is a peeling liner, or whether or not there is a releasing agent layer exerts no influence on the resistance to glass adhesive force.

However, comparison of the number of particles of Example 2 using the polyethylene terephthalate film which is not release-processed as the peeling liner with that of Comparative Example 4 using the peeling liner in which the release processing of the fluorosilicone-based releasing layer has been made reveals that Example 2 enables a reduction in the number of transfer foreign matter with no retransfer of the releasing agent.

1. A pressure-sensitive adhesive tape for protecting surface comprising: at least a base material film, a pressure-sensitive adhesive layer, and a peeling liner, the base material film having the pressure-sensitive adhesive layer on one surface thereof, and the peeling liner using an unprocessed plastic film which does not comprise a releasing layer being laminated on the pressure-sensitive adhesive layer.

2. The pressure-sensitive adhesive tape for protecting surface according to claim 1, wherein the peeling liner comprises polyethylene terephthalate or polyethylene naphthalate.

3. The pressure-sensitive adhesive tape for protecting surface according to claim 1, wherein the pressure-sensitive adhesive layer is an addition reaction-type silicone-based pressure-sensitive adhesive layer.

4. The pressure-sensitive adhesive tape for protecting surface according to claim 1, wherein a peeling force of the peeling liner from the pressure-sensitive adhesive layer surface is 1 N/50 mm or less.

5. The pressure-sensitive adhesive tape for protecting surface according to claim 1, wherein an adhesive force at normal temperature is 0.05 N/20 mm or less and an adhesive force after 260° C. reflow is 0.50 N/20 mm or less.
